(19) United States
(12) Patent Application Publication
(10) Pub. No.: US 2025/0116716 A1
(43) Pub. Date: Apr. 10, 2025

(54) CAPACITY ESTIMATION DEVICE AND CAPACITY ESTIMATION METHOD

(71) Applicant: DENSO CORPORATION, Kariya-city (JP)

(72) Inventors: Yuki HORI, Kariya-city (JP); Masaki UCHIYAMA, Kariya-city (JP); Taisuke KURACHI, Kariya-city (JP)

(73) Assignee: DENSO CORPORATION, Kariya-city (JP)

(21) Appl. No.: 18/984,097

(22) Filed: Dec. 17, 2024

Related U.S. Application Data
(63) Continuation of application No. PCT/JP2023/020527, filed on Jun. 1, 2023.

(30) Foreign Application Priority Data
Jun. 17, 2022 (JP) 2022-098233

(51) Int. Cl. G01R 31/388

(52) U.S. Cl. CPC G01R 31/388

(57) ABSTRACT

A capacity estimation device that estimates a capacity of a power storage unit at a time of charging the power storage unit includes: a control unit that reduces an average current in a predetermined current restriction section after a start of charging the power storage unit, the average current indicating an average value per unit time of a charging current flowing in the power storage unit; and an estimation unit that estimates the capacity based on a voltage change rate of the power storage unit after or within the current restriction section.

### CROSS-REFERENCE TO RELATED APPLICATION

The present application is a continuation application of International Application No. PCT/JP2023/020527, filed on Jun. 1, 2023, which claims priority to Japanese Patent Application No. 2022-098233, filed on Jun. 17, 2022. The contents of these applications are incorporated herein by reference in their entirety.

### BACKGROUND

### Technical Field

The present disclosure relates to a capacity estimation device and a capacity estimation method.

### Background Art

Disclosure regarding estimating the capacity of a secondary battery forming a battery pack has been conventionally known. For example, a unique point at which the voltage change rate of a secondary battery has a local maximum is detected, and the capacity corresponding to the unique point detected is estimated as the capacity of the secondary battery.

### SUMMARY

In the present disclosure, provided is a capacity estimation device as the following.

The capacity estimation device estimates a capacity of a power storage unit at a time of charging the power storage unit, the capacity estimation device including:

a control unit that reduces an average current in a predetermined current restriction section after a start of charging the power storage unit, the average current indicating an average value per unit time of a charging current flowing in the power storage unit; and

an estimation unit that estimates the capacity based on a voltage change rate of the power storage unit after or within the current restriction section.

The present disclosure also provides a capacity estimation device as the following.

The capacity estimation method estimates a capacity of a power storage unit at a time of charging the power storage unit, the capacity estimation method including:

reducing an average current in a predetermined current restriction section after a start of charging the power storage unit, the average current indicating an average value per unit time of a charging current flowing in the power storage unit; and

estimating the capacity based on a voltage change rate of the power storage unit after or within the current restriction section.

### BRIEF DESCRIPTION OF THE DRAWINGS

The object described above and another object, a feature, and an advantage of the present disclosure are further clarified by the following detailed description with reference to accompanying drawings. In the accompanying drawings:

FIG. 1 is a configuration diagram of a battery control device according to a first embodiment;

FIG. 2 is a graph showing a relationship between the capacity and the OCV at an initial time and after degradation;

FIG. 3 is a graph showing a voltage threshold;

FIG. 4 is a graph showing a relationship between the capacity, the OCV, and the voltage threshold;

FIG. 5 is a graph showing an aspect of detecting a specific capacity based on a local maximum of a differential value of the voltage;

FIG. 6 is a graph showing an aspect in which a local maximum, corresponding to the specific capacity, of a voltage change rate is deviated;

FIG. 7 is a diagram illustrating one factor of the occurrence of the unevenness of charge;

FIG. 8 is graphs illustrating one example of a method for controlling the average current;

FIG. 9 is a graph illustrating one example of the voltage change rate;

FIG. 10 is a flowchart illustrating one exemplary operation of a BMU according to the first embodiment;

FIG. 11 is a graph showing a relationship between current integrated values and a real part of impedance;

FIG. 12 is a graph showing an aspect of detecting the specific capacity based on a differential value of the real part of the impedance;

FIG. 13 is a flowchart illustrating one exemplary operation of a BMU according to a second embodiment;

FIG. 14 is graphs illustrating another example of the method for controlling the average current;

FIG. 15 is graphs illustrating another example of the method for controlling the average current;

FIG. 16 is a graph showing a modified example of estimation of the lithium-ion battery capacity; and

FIG. 17 is a table illustrating the frequency of an average current control.

### DETAILED DESCRIPTION OF THE PREFERRED EMBODIMENTS

### [PTL 1] JP 2014-167457 A

A secondary battery sometimes has a higher-capacity portion and a lower-capacity portion generated therein when charged. The secondary battery in which such unevenness in capacity (unevenness of charge) has occurred allows the capacity when the voltage change rate has a local maximum to be deviated from a specific capacity, and the accuracy of estimating the capacity may possibly be lowered.

The present disclosure has been made in view of the problem described above, and an object of the present disclosure is to provide a capacity estimation device and a capacity estimation method that can accurately estimate the capacity of a power storage unit.

The present disclosure is a capacity estimation device that estimates a capacity of a power storage unit at a time of charging the power storage unit, the capacity estimation device including:

a control unit that reduces an average current in a predetermined current restriction section after a start of charging the power storage unit, the average current indicating an average value per unit time of a charging current flowing in the power storage unit; and

an estimation unit that estimates the capacity based on a voltage change rate of the power storage unit after or within the current restriction section.

By reducing the average current in the current restriction section in which the unevenness of charge is likely to occur, the occurrence of the unevenness of charge is suppressed. Thereby, the capacity when the voltage change rate has a local maximum is prevented from being deviated from a specific capacity, and the capacity of the power storage unit can be accurately estimated.

The present disclosure is a capacity estimation method that estimates a capacity of a power storage unit at a time of charging the power storage unit, the capacity estimation method including:

reducing an average current in a predetermined current restriction section after a start of charging the power storage unit, the average current indicating an average value per unit time of a charging current flowing in the power storage unit; and

estimating the capacity based on a voltage change rate of the power storage unit after or within the current restriction section.

By reducing the average current in the current restriction section in which the unevenness of charge is likely to occur, the occurrence of the unevenness of charge is suppressed. Thereby, the capacity when the voltage change rate has a local maximum is prevented from being deviated from a specific capacity, and the capacity of the power storage unit can be accurately estimated.

Hereinafter, embodiments of the present disclosure are described with reference to the drawings. Identical parts in the drawings are given an identical reference sign, and the description is omitted.

### First Embodiment

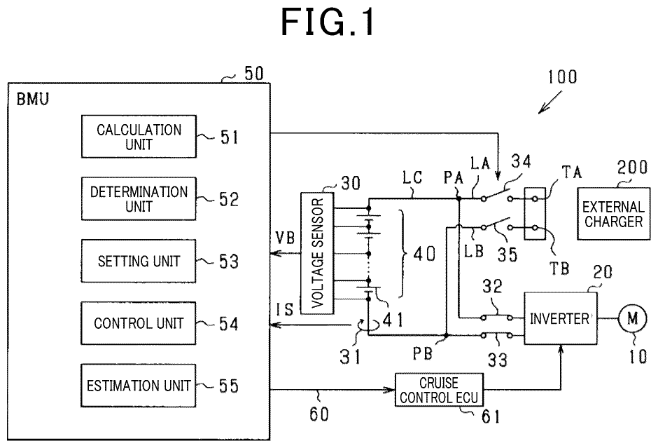

With reference to FIG. 1, a configuration example of a battery control device 100 according to a first embodiment is described. As shown in FIG. 1, a battery control device 100 includes a rotating electrical machine 10, an inverter 20, a voltage sensor 30, a current sensor 31, and first to fourth relay switches 32 to 35, a battery 40, and a BMU (Battery Management Unit) 50. The battery control device 100, for example, monitors the capacity and the charge-discharge state of the battery 40. In the present embodiment, the capacity of the battery 40 is an electric quantity [Ah] that can be discharged by the battery 40, and may be expressed as a remaining level.

One example of the battery 40 is an assembled battery formed by connecting a plurality of lithium-ion batteries 41 in series. Each of the lithium-ion batteries 41 is a secondary battery containing lithium as a charge carrier, and one containing lithium iron phosphate as a positive active material and graphite as a negative active material is used. The way of using the battery 40 is not particularly limited, and the battery 40 may be, for example, mounted to an electric vehicle or a hybrid vehicle and the power stored in the battery 40 is used to drive these vehicles. The lithium-ion batteries 41 forming the battery 40 are sometimes called battery cells.

The battery 40 is connected to the rotating electrical machine 10 via the inverter 20. The rotating electrical machine 10 inputs and outputs the power between the rotating electrical machine 10 and the battery 40, and imparts, during power running, propulsion to a vehicle by the power supplied from the battery 40. The rotating electrical machine 10 also generates power using braking energy of a vehicle and outputs the power to the battery 40 during regeneration.

The voltage sensor 30 detects a voltage between terminals of each of the lithium-ion batteries 41 forming the battery 40, and detects a battery voltage VB obtained by totaling these voltages between the terminals. The current sensor 31 is disposed on a connecting wire LC that connects the battery 40 to the inverter 20, and detects the magnitude and the direction of a charging/discharging current IS that is a current flowing into and out from the battery 40. The battery control device 100 also includes a temperature sensor which is not illustrated. The temperature sensor detects a temperature of the lithium-ion battery 41. The detected values of the sensors are input to the BMU 50.

The battery 40 is configured to be connectable to an external charger 200 via first and second external charging terminals TA, TB. The external charger 200 may be, for example, a DC quick charger. When the external charger 200 is connected to the first and second external charging terminals TA, TB, the battery 40 is charged at a constant current or a constant voltage by high-voltage DC power input from the external charger 200.

The first and second external charging terminals TA, TB are connected to the connecting wire LC via first and second charging paths LA, LB. Specifically, the first external charging terminal TA is, via the first charging path LA, connected to a first connection point PA between a positive terminal of the battery 40 on the connecting wire LC and the inverter 20. The second external charging terminal TB is, via the second charging path LB, connected to a second connection point PB between a negative terminal of the battery 40 on the connecting wire LC and the inverter 20.

The first relay switch 32 is disposed between the first connection point PA on the connecting wire LC and the inverter 20, and the second relay switch 33 is disposed between the second connection point PB on the connecting wire LC and the inverter 20. The first and second relay switches 32, 33 switch the connection state between the battery 40 and the rotating electrical machine 10. The third relay switch 34 is disposed on the first charging path LA, and the fourth relay switch 35 is disposed on the second charging path LB. The third and fourth relay switches 34, 35 switch the connection state between the battery 40 and the external charger 200.

The BMU 50 is a microcomputer formed of, for example, a CPU, a ROM, a RAM, and an input-output interface for inputting and outputting various signals, and has various functions. The BMU 50 is connected to the first to fourth relay switches 32 to 35, and switches the connection states of the first to fourth relay switches 32 to 35 based on the capacity of the battery 40. The BMU 50 is communicably connected to a cruise control ECU 61 via an vehicle-mounted network interface 60. The cruise control ECU 61 controls the inverter 20 and thus drives the rotating electrical machine 10.

The functions provided by the BMU 50 can be provided by software recorded in a tangible memory device and a computer that executes the software, only software, only hardware, or a combination thereof. For example, when the microcomputer is provided by an electronic circuit which is hardware, it can be provided by a digital circuit including a large number of logic circuits, or an analog circuit. For example, the microcomputer executes a program stored in a non-transitory tangible storage medium as its own storage. By executing the program, a method corresponding to the program is executed, or a function corresponding to the program is achieved. The storage may be, for example, a non-volatile memory. The program stored in the storage is updatable via a network such as the internet.

In the present embodiment, the BMU 50 also functions as a capacity estimation device that estimates the capacity of the lithium-ion battery 41. The BMU 50 estimates the capacity of the lithium-ion battery 41 based on the detected values input from the sensors. The BMU 50 includes, as functions that process the detected values input from the sensors, a calculation unit 51, a determination unit 52, a setting unit 53, a control unit 54, and an estimation unit 55. These functions are described later in detail.

As a method for estimating the capacity of the lithium-ion battery 41, there is known a method for using SOC-OCV characteristics showing a correlationship between the state of charge (SOC) and the open circuit voltage (OCV) of the lithium-ion battery 41. The open circuit voltage OCV is a voltage between both terminals of the lithium-ion battery 41 with no load applied thereto (lithium-ion battery 41 in an open circuit state). The SOC [%] is represented by (present capacity/full capacity) of the lithium-ion battery 41×100, and represents the ratio of the present capacity to the full capacity of the lithium-ion battery 41.

The lithium-ion battery 41 containing active materials such as lithium iron phosphate and graphite has a stable open-circuit voltage in a wide range of SOC. A region in which a change in the open-circuit voltage OCV is small is called a plateau region. In the plateau region, a voltage change rate of the open-circuit voltage OCV with respect to the capacity of the lithium-ion battery 41 is a predetermined change rate or lower. In the plateau region, it is sometimes difficult to calculate the SOC of the lithium-ion battery 41 using the SOC-OCV characteristics.

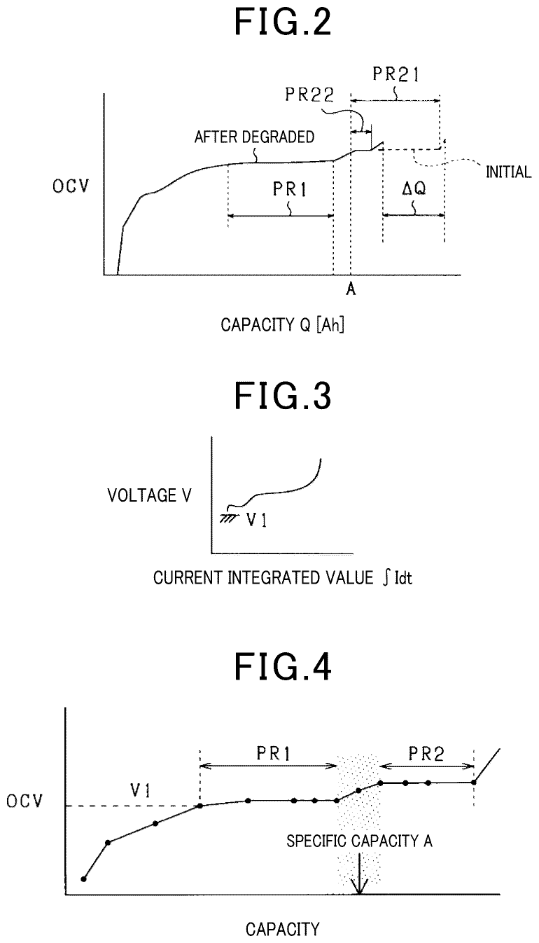

FIG. 2 is a graph showing a relationship between the capacity Q and the OCV of the lithium-ion battery 41 at an initial time and after degradation. The initial time referred to herein means the time when the lithium-ion battery 41 is new. The vertical axis in FIG. 2 represents the OCV, and the horizontal axis represents the capacity Q [Ah] of the lithium-ion battery 41. Reference signs PR1, PR21, and PR22 in FIG. 2 represent plateau regions. The plateau regions PR1, 22 represent plateau regions when the lithium-ion battery 41 has been degraded, and the plateau region PR21 represents a plateau region when the lithium-ion battery 41 is new. The plateau region when degraded partially overlaps the plateau region when new (plateau region PR22). As shown in FIG. 2, the voltage change rate of the open-circuit voltage OCV with respect to the capacity of the lithium-ion battery 41 is higher between the plateau regions PR1 and PR22 than in the plateau regions PR1, PR22. When the capacity is a specific value (hereinafter, called a specific capacity A) between the plateau regions PR1 and PR22, the voltage change rate has a local maximum. Further, the specific capacity A of the lithium-ion battery 41 when the voltage change rate has a local maximum is almost identical and is not changed between the lithium-ion battery 41 of initial time and the lithium-ion battery 41 after degradation when the lithium-ion battery 41 is charged over time. Therefore, when the voltage change rate has a local maximum, the specific capacity A at that time can be estimated as the capacity of the lithium-ion battery 41. The specific capacity A is the capacity fixed by a structural change of a negative electrode of the lithium-ion battery 41. AQ in FIG. 2 represents the capacity decreased by degradation of the lithium-ion battery 41.

Next, a condition for estimating the capacity of the lithium-ion battery 41 is described with reference to FIG. 3. FIG. 3 is a graph showing a voltage threshold. The vertical axis in FIG. 3 represents the voltage of the lithium-ion battery 41, and the horizontal axis represents integrated values of a charging current flowing in the lithium-ion battery 41. Hereinafter, the integrated value of a charging current flowing in the lithium-ion battery 41 is sometimes simply called a current integrated value. As shown in FIG. 3, when the charge of the lithium-ion battery 41 is started, the current integrated value increases, and the voltage of the lithium-ion battery 41 rises along with the increase. In the present embodiment, the condition for estimating the capacity of the lithium-ion battery 41 is that the voltage of the lithium-ion battery 41 at the start of the charge is higher than a voltage threshold V1. One example of a method for setting the voltage threshold V1 is described with reference to FIG. 4.

FIG. 4 is, similarly to FIG. 2, a graph showing a relationship between the capacity and the OCV of the lithium-ion battery 41. As shown in FIG. 4, the voltage change rate of the OCV with respect to the capacity of the lithium-ion battery 41 has, due to a structural change of a negative electrode of the lithium-ion battery 41, a local maximum between two plateau regions PR1, PR2 in which the voltage change rate of the OCV is the predetermined change rate or lower. Therefore, when the voltage of the lithium-ion battery 41 is lower than the OCV of the plateau region PR1 having a lower OCV, a local maximum of the voltage change rate of the OCV, which is attributed to a structural change of a negative electrode of the lithium-ion battery 41, is not generated.

Therefore, as shown in FIG. 4, the voltage threshold V1 may be set to, for example, the lowest voltage in the plateau region PR1 of the two plateau regions PR1, PR2.

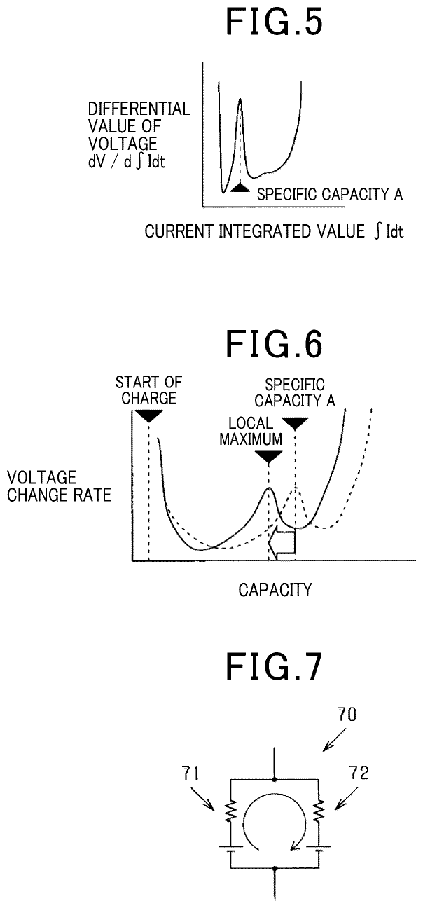

FIG. 5 is a graph showing an aspect of detecting the specific capacity A based on a local maximum of a differential value of the voltage of the lithium-ion battery 41. The vertical axis in FIG. 5 represents differential values of the voltage of the lithium-ion battery 41, and the horizontal axis represents current integrated values. When determining that the voltage of the lithium-ion battery 41 is higher than the voltage threshold V1, the BMU 50 calculates a differential value of the voltage of the lithium-ion battery 41. Specifically, the BMU 50 calculates a differential value of the voltage with respect to a current integrated value. The differential value of the voltage referred to herein represents a voltage change rate with respect to the capacity of the lithium-ion battery 41. The BMU 50 determines whether the differential value of the voltage with respect to the current integrated value has a local maximum. When the differential value of the voltage with respect to the current integrated value has a local maximum as shown in FIG. 5, the BMU 50 estimates the capacity at that time of the lithium-ion battery 41 as the specific capacity A. The capacity in FIG. 5 is the capacity corresponding to between two local minimums.

A secondary battery, such as the lithium-ion battery 41, sometimes has a higher-capacity portion and a lower-capacity portion generated therein when charged. Such unevenness in capacity is called “unevenness of charge” in the present embodiment. The unevenness in capacity can also occur during discharge, but is here described only for charge scenes, and the description of discharge scenes is omitted. The disclosers have focused on a feature in which the capacity when the voltage change rate has a local maximum during charge is deviated from the specific capacity A in a state in which the unevenness of charge has occurred. This feature is described with reference to FIG. 6. FIG. 6 is a graph showing an aspect in which a local maximum, corresponding to the specific capacity A, of the voltage change rate is deviated. When quick charge of the lithium-ion battery 41 is started from a low-capacity state (for example, 20%), the capacity when the voltage change rate has a local maximum is shifted from the specific capacity A to the lower-capacity side as shown in FIG. 6. In this case, if the capacity of the lithium-ion battery 41 when the voltage change rate has a local maximum is estimated as the specific capacity A, the estimated capacity is deviated from the correct capacity. Main causes of the deviation shown in FIG. 6 are occurrence of unevenness of charge due to a large current, such as quick charge, flowing in the lithium-ion battery 41, and increase of the unevenness of charge that has occurred.

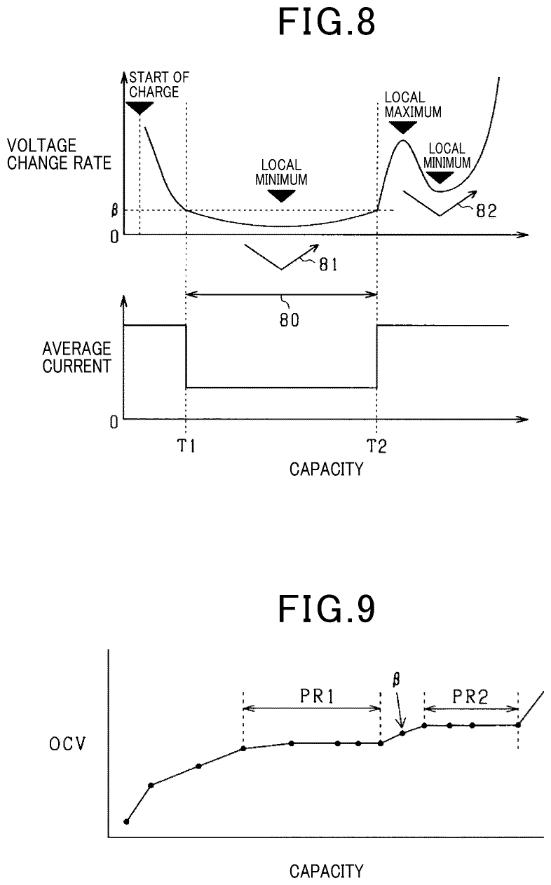

Next, one cause of the increase of the unevenness of charge is described with reference to FIG. 7. FIG. 7 represents the lithium-ion battery 41 as an equivalent circuit 70 that is schematic. The equivalent circuit 70 is formed of a part 71 and a part 72. Both the parts have a resistance and an OCV. A case is considered in which the difference in the OCV between these parts 71 and 72 is tiny. The tiny difference in the OCV means that the current flowing between the parts is tiny. The charge performed in this state allows the charging current to flow in only a part having a lower resistance, and only the capacity of the part having a lower resistance is unilaterally increased. This phenomenon increases the unevenness of charge. In order to prevent this increase of the unevenness of charge, the time for eliminating the unevenness of charge is secured when the current flowing between the parts is tiny. That is, in the present embodiment, the average current flowing in the lithium-ion battery 41 is, during charge, reduced in a capacity zone in which the difference in the OCV between parts is tiny. Hereinafter, the “capacity zone in which the difference in the OCV is tiny” is called an intermediate SOC zone. The intermediate SOC zone is a part or an entire part of the plateau region PR1 in FIG. 4. A detailed control is described with reference to FIG. 8.

The upper graph in FIG. 8 represents a relationship between the voltage change rate of the lithium-ion battery 41 and the capacity of the lithium-ion battery 41. The lower graph in FIG. 7 represents a relationship between the average current flowing in the lithium-ion battery 41 and the capacity of the lithium-ion battery 41. After the start of charging the lithium-ion battery 41, the BMU 50 determines whether the capacity of the lithium-ion battery 41 is a capacity in the intermediate SOC zone. For this determination, the voltage change rate of the lithium-ion battery 41 is used. Specifically, as shown in FIG. 8, the BMU 50 determines whether the voltage change rate is a first predetermined value (β) or lower. When the voltage change rate is β or lower, the BMU 50 determines that the capacity of the lithium-ion battery 41 is a capacity in the intermediate SOC zone. As the value β, a value of the voltage change rate between the plateau regions PR1 and PR2 in FIG. 9 may be employed.

In an example shown in FIG. 8, the voltage change rate gradually lowers after the start of the charge, becomes β or lower at the timing of the capacity becoming T1, and becomes higher than β at the timing of the capacity becoming T2. T1 is lower than T2 (T1<T2). Here, for the convenience of description, T1 and T2 are respectively called a timing T1 and a timing T2. The timing T1 means the time at which the capacity of the lithium-ion battery 41 has become T1. The same applies to the timing T2. As shown in FIG. 8, the BMU 50 reduces the average current flowing in the lithium-ion battery 41 at the timing T1. The “average current” in the present embodiment is defined as an average value of a charging current per unit time. The phrase “reduce the average current” means reducing the average current compared to the average current before the timing T1.

The BMU 50 maintains a state in which the average current is reduced, until the voltage change rate becomes higher than β. That is, the BMU 50 reduces the average current in a current restriction section 80 from the timing T1 to the timing T2. Then, the BMU 50 increases the average current, which has been reduced, at the timing of the voltage change rate becoming higher than β, that is, the timing T2. The phrase “increase the average current” means increasing the average current compared to the average current in the current restriction section 80. In the example shown in FIG. 8, the average current after the timing T2 is described as having the same magnitude as the average current before the timing T1, but is not limited to this example. The average current after the timing T2 may be larger or smaller than the average current before the timing T1 as long as the average current after the timing T2 satisfies being large compared to the average current in the current restriction section 80.

Thus, the BMU 50 reduces the average current flowing in the lithium-ion battery 41 in the current restriction section 80 in which the voltage change rate is β or lower, that is, the intermediate SOC zone in which the unevenness of charge is likely to occur. Thereby, even when the unevenness of charge has occurred, it is possible to buy time necessary for naturally eliminating the unevenness of charge. As a result, the occurrence of the unevenness of charge is suppressed. Thereby, the deviation described in FIG. 6 is suppressed, and high-accuracy capacity estimation becomes possible.

The BMU 50 estimates the capacity of the lithium-ion battery 41 after the current restriction section 80. As described in FIG. 5, the BMU 50 determines whether the voltage change rate of the lithium-ion battery 41 has a local maximum. When the voltage change rate has a local maximum, the BMU 50 estimates, as the capacity of the lithium-ion battery 41, the capacity corresponding to the local maximum. The expression may be that the BMU 50 estimates, as the capacity of the lithium-ion battery 41, the capacity corresponding to between two local minimums. The expression may also be that the BMU 50 estimates, as the capacity of the lithium-ion battery 41, the capacity corresponding to a local maximum between two local minimums. Further, the expression may be that the BMU 50 estimates the capacity of the lithium-ion battery 41 in a section from when the voltage change rate is negatively sloped and then positively sloped as shown in a reference sign 81 until when the voltage change rate is negatively sloped and then positively sloped as shown in a reference sign 82.

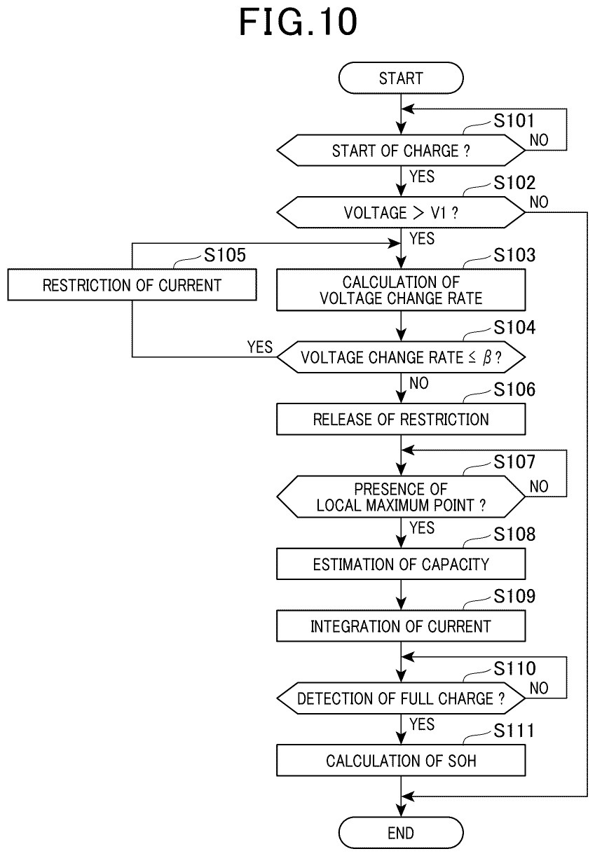

Next, one exemplary operation of the BMU 50 is described with reference to the flowchart of FIG. 10. The processes shown in FIG. 10 are repetitively executed at a predetermined time interval.

In step S101, the BMU 50 determines whether the charge of the lithium-ion battery 41 (battery 40) has been started. The determination method is not limited, and for example, the BMU 50 may determine that the charge has been started, when receiving a signal indicating connection of the external charger 200 to a vehicle. When the BMU 50 determines that the charge has been started (YES in step S101), the process goes to step S102. On the other hand, when the BMU 50 determines that the charge has not been started (NO in step S101), the process is repetitively executed.

In step S102, the BMU 50 determines whether the voltage of the lithium-ion battery 41 is higher than the voltage threshold V1 (see FIG. 3). When the BMU 50 determines that the voltage of the lithium-ion battery 41 is higher than the voltage threshold V1 (YES in step S102), the process goes to step S103. On the other hand, when determining that the voltage of the lithium-ion battery 41 is the voltage threshold V1 or lower (NO in step S102), the BMU 50 ends the process.

In step S103, the BMU 50 calculates a voltage change rate of the lithium-ion battery 41. The process goes to step S104, and the BMU 50 determines whether the voltage change rate is β or lower (see FIG. 8). When the BMU 50 determines that the voltage change rate is β or lower, the process goes to step S105. The process in step S104 corresponds to the determination unit 52 of the BMU 50.

In step S105, the BMU 50 sets, at the timing T1 of the voltage change rate becoming β or lower, the current restriction section 80 in which the average current flowing in the lithium-ion battery 41 is reduced. The state in which the average current is reduced is maintained until the voltage change rate becomes higher than β. The process in step S105 corresponds to the setting unit 53 and the control unit 54 of the BMU 50. When the charge goes on and the BMU 50 determines that the voltage change rate is higher than β, the BMU 50 ends the current restriction section 80 and releases the restriction of the current, and increases the average current that has been reduced (step S106).

The process goes to step S107, and the BMU 50 determines whether the voltage change rate of the lithium-ion battery 41 has a local maximum (see FIG. 8). When the BMU 50 determines that the voltage change rate of the lithium-ion battery 41 has a local maximum (YES in step S107), the process goes to step S108. On the other hand, when the BMU 50 determines that the voltage change rate of the lithium-ion battery 41 does not have a local maximum (NO in step S107), the process is repetitively executed.

In step S108, the BMU 50 estimates, as the capacity of the lithium-ion battery 41, the capacity corresponding to the local maximum. The process in step S108 corresponds to the estimation unit 55 of the BMU 50.

In step S109, the BMU 50 calculates a current integrated value by integrating the current applied and the time taken since the local maximum of the voltage change rate. The process goes to step S110, and the BMU 50 determines whether the state of charge of the lithium-ion battery 41 is full charge. When the BMU 50 determines that state of charge of the lithium-ion battery 41 is full charge (YES in step S110), the process goes to step S111. On the other hand, when the BMU 50 determines that the state of charge of the lithium-ion battery 41 is not full charge (NO in step S110), the process is repetitively executed.

In step S111, the BMU 50 calculates the SOH (State of Health) indicating the degradation state of the lithium-ion battery 41. The SOH [%] is represented by (present full capacity/full capacity when new) of the lithium-ion battery 41×100, and represents the ratio of the present full capacity to the full capacity when new of the lithium-ion battery 41. One example of a SOH calculation method is described. The BMU 50 adds, to the capacity of the lithium-ion battery 41 estimated in step S108, the current integrated value calculated in step S109, and thus calculates the full-charge capacity as the present full capacity. The full capacity when new is known, and therefore, when the present full capacity is calculated, the SOH is calculated by the above formula. The process in step S111 corresponds to the calculation unit 51 of the BMU 50.

The first embodiment described above in detail can give the following effects.

The BMU 50 (control unit 54) reduces the average current in the predetermined current restriction section 80 after the start of charging the lithium-ion battery 41 (power storage unit), the average current indicating an average value per unit time of a charging current flowing in the lithium-ion battery 41. The BMU 50 (estimation unit 55) estimates the capacity based on the voltage change rate of the lithium-ion battery 41 after or within the current restriction section. By reducing the average current in the current restriction section 80 in which the unevenness of charge is likely to occur, it is possible to buy time necessary for naturally eliminating the unevenness of charge even when the unevenness of charge has occurred. As a result, the occurrence of the unevenness of charge is suppressed. Thereby, the deviation described in FIG. 6 is suppressed, and it is possible to accurately estimate the capacity of the lithium-ion battery 41.

The BMU 50 sets the current restriction section 80 based on a parameter that changes by charging the lithium-ion battery 41. In FIG. 8, it is described that the BMU 50 sets the current restriction section 80 using the voltage change rate (β) of the lithium-ion battery 41. By using β, the current restriction section 80 can be set in the intermediate SOC zone in which the unevenness of charge is likely to occur. However, the parameter for restricting the average current is not limited to the voltage change rate. The parameter for restricting the average current can be any indicator that enables recognition that the charge is halfway through. For example, the BMU 50 may reduce the average current when the voltage during charge is lower than a predetermined value, may reduce the average current when the current integrated quantity during charge is lower than a predetermined value, or may reduce the average current when the charge time is lower than a predetermined value. The voltage change rate, the voltage, the current integrated quantity, and the charge time during charge correspond to parameters that change by charging the lithium-ion battery 41.

The BMU 50 sets, as the starting point of the current restriction section 80, a point at which the voltage change rate is a first predetermined value or lower, and sets, as the end point of the current restriction section 80, a point at which the voltage change rate is higher than the first predetermined value. One example of the first predetermined value is β. As described in FIG. 8, the BMU 50 sets, as the starting point of the current restriction section 80, the timing T1 at which the voltage change rate becomes β or lower, and sets, as the end point of the current restriction section 80, the timing T2 at which the voltage change rate becomes higher than β. By thus using β, the current restriction section 80 can be set in the intermediate SOC zone in which the unevenness of charge is likely to occur.

The BMU 50 estimates, as the capacity of the lithium-ion battery 41, the capacity corresponding to between two local minimums of the voltage change rate after or within the current restriction section. Since the deviation is suppressed by reducing the average current, it is possible to accurately estimate the capacity of the lithium-ion battery 41. In FIG. 8, the BMU 50 estimates the capacity of the lithium-ion battery 41 after the current restriction section.

The BMU 50 calculates the degradation state of the lithium-ion battery 41 based on the estimated capacity of the lithium-ion battery 41, the current integrated value obtained by integrating the charging current applied and the time taken from the estimation of the capacity until the lithium-ion battery 41 satisfies a full-charge condition, and the full capacity when the lithium-ion battery 41 is new. The present embodiment can give a high-accuracy degradation state by calculating the degradation state of the lithium-ion battery 41 using the capacity of the lithium-ion battery 41 that has been accurately estimated.

### Second Embodiment

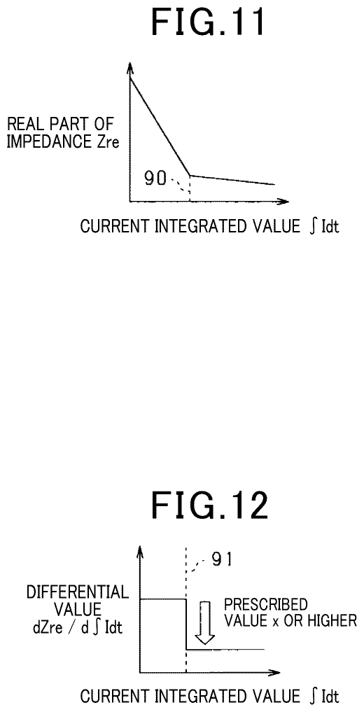

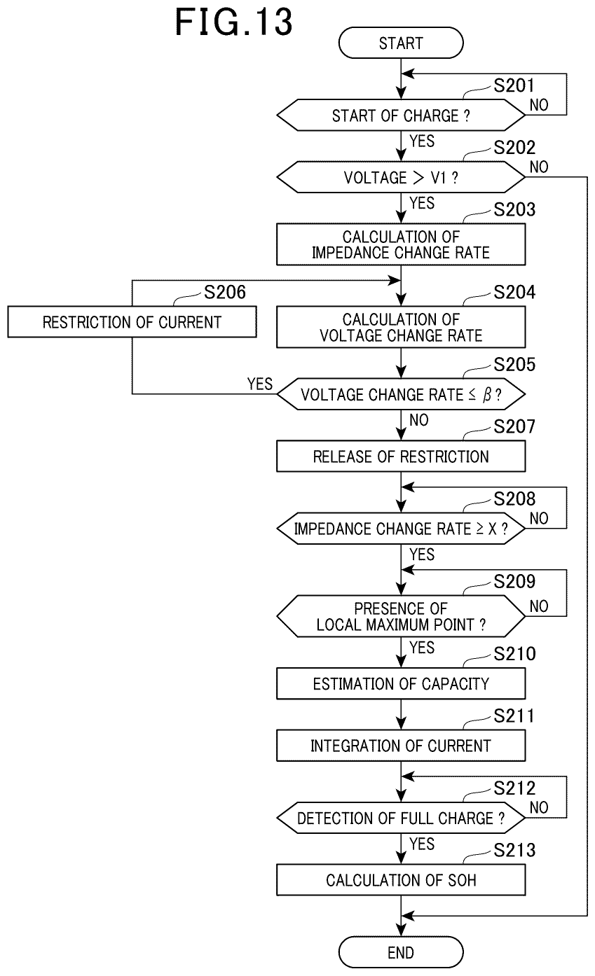

Next, a second embodiment is described with reference to FIGS. 11 to 13. In the flowchart of FIG. 13, the processes of steps S201 to S202, steps S204 to S207, and steps S209 to S213 are the same as the processes of steps S101 to S102, steps S103 to S106, and steps S107 to S111 shown in FIG. 10, and therefore, the description is omitted. Hereinafter, differences are mainly described.

When the current charging the lithium-ion battery 41 is larger than a predetermined current in the determination of whether the voltage change rate with respect to the capacity of the lithium-ion battery 41 has a local maximum, it is difficult to distinguish the local maximum. To deal with this difficulty, the discloser has focused on a feature shown in FIG. 11, in which, during charge of the lithium-ion battery 41, the voltage change rate of a real part Zre of impedance in the lithium-ion battery 41 with respect to the capacity greatly changes after the specific capacity A at which the voltage change rate has a local maximum. The impedance can be calculated based on the amplitude of the AC voltage and the amplitude of the AC current.

A reason of the change in the voltage change rate of the real part Zre of the impedance is that the reaction heat during charge is decreased due to a change of the stage of a negative electrode, the rise of temperature becomes mild due to the decrease of the reaction heat, and the decrease of the real part Zre of the impedance also becomes mild due to the rise of temperature being mild. Therefore, the BMU 50 may determine that the voltage change rate has a local maximum when the voltage change rate of the impedance in the lithium-ion battery 41 with respect to the capacity changes beyond a predetermined degree.

One example of a specific method is described. First, the BMU 50 calculates the real part Zre of the impedance in the lithium-ion battery 41. Subsequently, the BMU 50 calculates a differential value of the real part Zre of the impedance with respect to a current integrated value (the voltage change rate of the impedance with respect to the capacity of the lithium-ion battery 41) (step S203 in FIG. 13). The BMU 50 determines whether the voltage change rate of the real part Zre of the impedance has greatly changed (step S208 in FIG. 13). Specifically, as shown in FIG. 12, the BMU 50 determines whether the differential value of the real part Zre of the impedance with respect to the current integrated value has changed by a predetermined value x or higher. This configuration enables the BMU 50 to determine that the voltage change rate with respect to the capacity of the lithium-ion battery 41 has a local maximum even when the current charging the lithium-ion battery 41 is larger than a predetermined current. The predetermined value x corresponds to a fifth predetermined value.

In place of the real part Zre of the impedance in the lithium-ion battery 41, an imaginary part Zim of the impedance, an absolute value of the impedance, or a phase of the impedance can also be used. Further, in place of the voltage change rate of the real part Zre of the impedance, the change rate of the temperature of the lithium-ion battery 41 can also be used. That is, the BMU 50 may estimate that the voltage change rate has a local maximum when the change rate of the temperature related to the lithium-ion battery 41 or the voltage change rate of the impedance in the lithium-ion battery 41 changes beyond the predetermined value x.

### <Modified Examples>

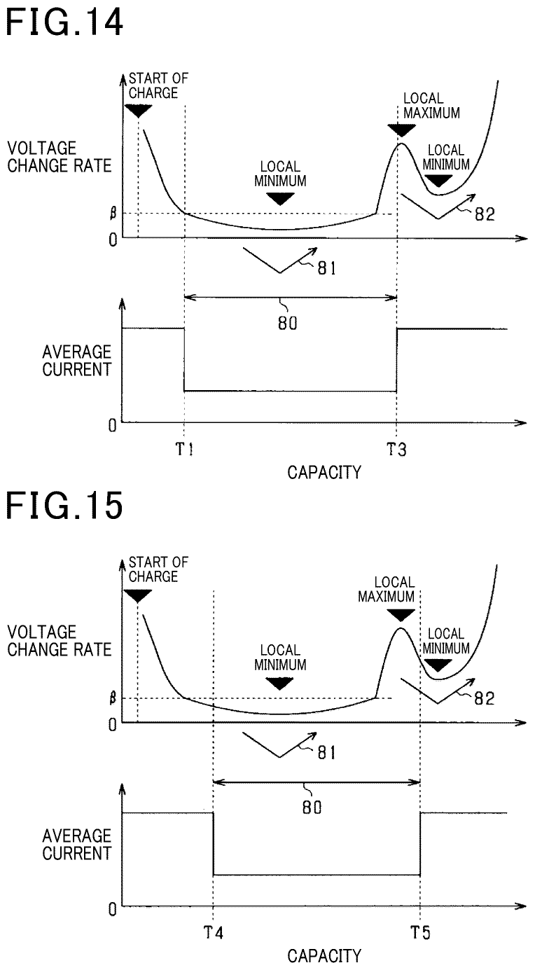

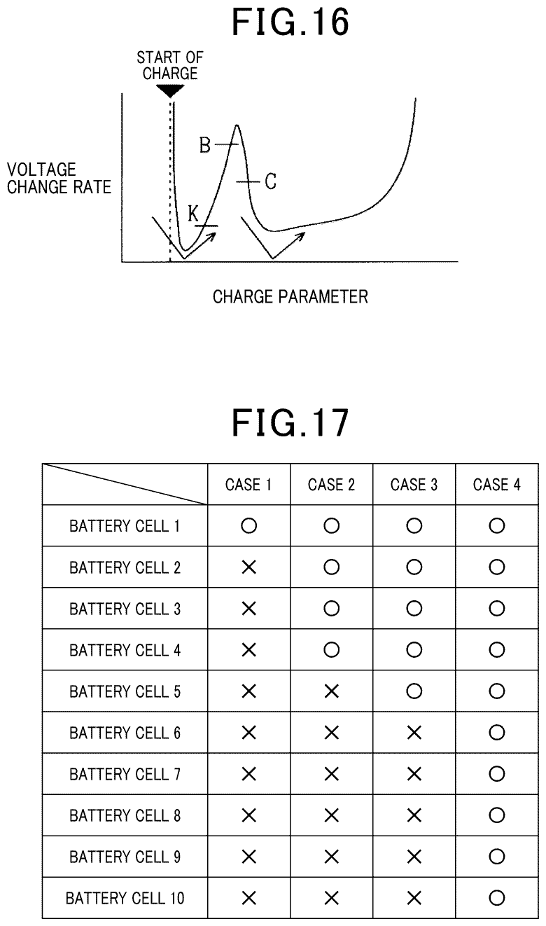

A part of the configurations of the embodiments may be modified. Hereinafter, modified examples are described.
In the embodiments, the power storage unit is described as being formed of the lithium-ion battery 41, but is not limited thereto, and may be formed of a capacitor.
The end point of the current restriction section 80, that is, the timing of increasing the average current is not limited to the timing T2. The timing of increasing the average current can be any timing as long as the condition that the voltage change rate is higher than β is satisfied. For example, as shown in FIG. 14, the BMU 50 may increase the average current at a timing T3 immediately before the voltage change rate has a local maximum. In other words, the BMU 50 may set, as the end point of the current restriction section 80, a point at which the voltage change rate is higher than the first predetermined value and which is immediately before the voltage change rate has a local maximum. T3 shown in FIG. 14 indicates the capacity, but is described as a timing for the convenience of description. The timing T3 means the time at which the capacity of the lithium-ion battery 41 has become T3. The voltage change rate is higher than β at the timing T3, and therefore, the condition is satisfied. By reducing the average current immediately before the voltage change rate has a local maximum, it is possible to buy more time necessary for naturally eliminating the unevenness of charge. In FIG. 14, the BMU 50 estimates the capacity of the lithium-ion battery 41 after the current restriction section.
The starting point of the current restriction section 80, that is, the timing of reducing the average current is not limited to the timing T1. The timing of reducing the average current can be any timing as long as the condition that the voltage change rate is β or lower is satisfied. For example, as shown in FIG. 15, the BMU 50 may reduce the average current at a timing T4. T4 shown in FIG. 15 indicates the capacity, but is described as a timing for the convenience of description. The timing T4 means the time at which the capacity of the lithium-ion battery 41 has become T4. The voltage change rate is β or lower at the timing T4, and therefore, the condition is satisfied. As shown in FIG. 15, the BMU 50 may increase the average current at a timing T5 that comes after the voltage change rate has a local maximum but until the voltage change rate has a local minimum. T5 shown in FIG. 15 indicates the capacity, but is described as a timing for the convenience of description. The timing T5 means the time at which the capacity of the lithium-ion battery 41 has become T5. The voltage change rate is higher than β at the timing T5, and therefore, the condition is satisfied. By controlling the average current at these timings, it is possible to buy more time necessary for naturally eliminating the unevenness of charge. In FIG. 15, the BMU 50 estimates the capacity of the lithium-ion battery 41 within the current restriction section.
As the method for reducing the average current, a step method has been picked up in FIG. 8. However, the method is not limited to the step method, and a slope method or an overshoot method may also be used. The “step method” referred to herein is a method for stepwise changing the average current from a certain magnitude to a smaller magnitude. The “slope method” is a method for gradually reducing the average current from a certain magnitude along a predetermined slope. The “overshoot method” is a method for reducing the average current beyond a target value when changing the average current from a certain magnitude to a smaller magnitude. The method may be not only simply reducing the average current, but also intermittently flowing the average current by repeating charge and breaks. The average current at the breaks need not be zero.
When the BMU 50 reduces the average current in the current restriction section 80, the lower the temperature of the lithium-ion battery 41, the more the average current may be reduced. A reason for this is that the unevenness of charge is likely to be expanded at low temperatures, and the effect of suppressing the expansion of the unevenness of charge is higher the smaller the average current is. As a parameter, the temperature of the lithium-ion battery 41 has been uesd. However, the parameter is not limited to the temperature of the lithium-ion battery 41, and temperature correlated to the temperature of the lithium-ion battery 41 may be used. The “temperature correlated to the temperature of the lithium-ion battery 41” is, for example, external temperature.
When the BMU 50 reduces the average current in the current restriction section 80, the longer the lapse of time from the production of the lithium-ion battery 41, the more the average current may be reduced. A reason for this is that a battery for which it has been long since the production thereof is degraded. The more degraded the battery is, the more likely the unevenness of charge is increased, and the effect of suppressing the expansion of the unevenness of charge is higher the smaller the average current is.
When the BMU 50 ends the current restriction section 80 and releases the restriction of the current, and increases the average current that has been reduced, the higher the temperature of the lithium-ion battery 41, the more the average current may be reduced. A reason for this is that the unevenness of charge is less likely to occur at high temperatures. As a parameter, the temperature of the lithium-ion battery 41 has been used. However, the parameter is not limited to the temperature of the lithium-ion battery 41, and temperature correlated to the temperature of the lithium-ion battery 41 may be used. The “temperature correlated to the temperature of the lithium-ion battery 41” is, for example, external temperature.
When the BMU 50 ends the current restriction section 80 and releases the restriction of the current, and increases the average current that has been reduced, the shorter the lapse of time from the production of the lithium-ion battery 41, the more the average current may be increased. A reason for this is that the shorter the lapse of time from production the less degraded the battery is, and unevenness of charge is less likely to occur.
In FIGS. 8, 14, and 15, the horizontal axis in the graph has been described as capacity, but is not limited thereto. The horizontal axis in the graph can be any parameter correlated to the capacity. For example, the horizontal axis in the graph may be charge time, SOC, or the like.
The BMU 50 may determine that the voltage change rate has a local maximum when, as shown in FIG. 16, after the start of charging the lithium-ion battery 41, the voltage change rate goes from lower than a second predetermined value K, beyond a third predetermined value B higher than the second predetermined value K, and then to less than a fourth predetermined value C lower than the third predetermined value B. The charge parameter set as the horizontal axis in FIG. 16 is a parameter correlated to the charge time, and the time, the capacity of the lithium-ion battery 41, the current integrated value, the temperature of the lithium-ion battery 41, the impedance in the lithium-ion battery 41, or the like can be employed. The predetermined values K, B, and C are set so as to correspond to the section from the voltage change rate being negatively sloped and then positively sloped to negatively sloped and then positively sloped. This configuration enables the BMU 50 to easily determine that the voltage change rate has a local maximum, based on the comparison of the magnitude between the voltage change rate and the three predetermined values K, B, and C.
As described above, the battery 40 includes a plurality of lithium-ion batteries 41. The BMU 50 may compare the magnitude between the voltage change rate of any one of the plurality of lithium-ion batteries 41 and β. The BMU 50 may compare the magnitude between the voltage change rates of two or more of the plurality of lithium-ion batteries 41 and β. The BMU 50 may compare the magnitude between the voltage change rates of all the lithium-ion batteries 41 and β. Here, a case is described in which the BMU 50 compares the magnitude between the voltage change rates of all the lithium-ion batteries 41 and β. In this case, when the BMU 50 ends the current restriction section 80 and releases the restriction of the current, and increases the average current, the voltage change rates of all the lithium-ion batteries need not be higher than β. This point is described using FIG. 17. In FIG. 17, as one example, ten lithium-ion batteries 41 are included. The battery cells in FIG. 17 represent lithium-ion batteries. The circles in FIG. 17 indicate that the voltage change rate is higher than β, and the crosses indicate that the voltage change rate is β or lower.

Regarding a case 1 in FIG. 17, one lithium-ion battery 41 has a voltage change rate of higher than β, and the other nine lithium-ion batteries 41 have a voltage change rate of β or lower. When at least one voltage change rate is higher than β, the BMU 50 may end the current restriction section 80 and release the restriction of the current, and increase the average current that has been reduced. Thereby, the charge time is shortened compared to the cases in which the average current is reduced until all the lithium-ion batteries 41 have voltage change rates of higher than β.

Regarding a case 2 in FIG. 17, four lithium-ion batteries 41 have a voltage change rate of higher than β, and the other six lithium-ion batteries 41 have a voltage change rate of β or lower. When less than half of the voltage change rates are higher than β, the BMU 50 may end the current restriction section 80 and release the restriction of the current, and increase the average current that has been reduced. Thereby, the charge time is shortened compared to the cases in which the average current is reduced until all the lithium-ion batteries 41 have a voltage change rates of higher than β.

Regarding a case 3 in FIG. 17, five lithium-ion batteries 41 have a voltage change rate of higher than β, and the other five lithium-ion batteries 41 have a voltage change rate of β or lower. When half or more of the voltage change rates are higher than β, the BMU 50 may end the current restriction section 80 and release the restriction of the current, and increase the average current that has been reduced. Thereby, the charge time is shortened compared to the cases in which the average current is reduced until all the lithium-ion batteries 41 have a voltage change rates of higher than β.

Regarding a case 4 in FIG. 17, all the lithium-ion batteries 41 have a voltage change rate of higher than β. When all the voltage change rates are higher than β, the BMU 50 may end the current restriction section 80 and release the restriction of the current, and increase the average current that has been reduced. Thereby, it is possible to buy time necessary for naturally eliminating the unevenness of charge in all the ten lithium-ion batteries 41. As a result, the occurrence of the unevenness of charge is suppressed in all the ten lithium-ion batteries 41. This case 4 is effective when there is a difference in the remaining level between the ten lithium-ion batteries 41.

The execution frequency of the cases 1 to 4 is not particularly limited, but, is for example, case 1>case 2>case 3>case 4. Suppose, the battery 40 is charged ten times. In this case, one example of the execution frequency is four times of the case 1, three times of the case 2, two times of the case 3, and one time of the case 4. Thus, by focusing on the number of the lithium-ion batteries 41 used for the determination of the magnitude with respect to β, and thus increasing the average current, it is possible to shorten the charge time or buy time necessary for naturally eliminating the unevenness of charge.

The execution frequency of the cases 1 to 4 may be expressed as follows. (i) When determining that one or more but less than half of the lithium-ion batteries 41 has a voltage change rate of higher than β, the BMU 50 releases the restriction of the current and increases the average current that has been reduced, without determining whether all the lithium-ion batteries 41 have a voltage change rate of higher than β. (ii) When determining that half or more of the lithium-ion batteries 41 have a voltage change rate of higher than β, the BMU 50 releases the restriction of the current and increases the average current that has been reduced, without determining whether all the lithium-ion batteries 41 have a voltage change rate of higher than β. When the charge is performed a plurality of times in a predetermined period, the frequency of executing the control of (i) is, with respect to the number of times of charge, higher than the frequency of executing the control of (ii). (i) corresponds to the case 2, and (ii) corresponds to the case 3. The frequency of executing the control of (i) is three of ten times, and the frequency of executing the control of (ii) is two of ten times. That is, the frequency of the controls is frequency of (i)>frequency of (ii).

(iii) When determining that one lithium-ion battery 41 has a voltage change rate of higher than β, the BMU 50 releases the restriction of the current and increases the average current that has been reduced, without determining whether all the lithium-ion batteries 41 have a voltage change rate of higher than β. (iv) When determining that all the lithium-ion batteries 41 have a voltage change rate of higher than β, the BMU 50 releases the restriction of the current and increases the average current that has been reduced. When the charge is performed a plurality of times in a predetermined period, the frequency of executing the control of (iii) is, with respect to the number of times of charge, higher than the frequency of executing the control of (iv). (iii) corresponds to the case 1, and (iv) corresponds to the case 4. The frequency of executing the control of (iii) is four of ten times, and the frequency of executing the control of (iv) is one of ten times. That is, the frequency of the controls is frequency of (iii)>frequency of (iv). The frequency of (iv) may be low, and may be, for example, about once every few days. This is because it takes a period of a few days until there is a difference in the remaining level between the plurality of lithium-ion batteries 41.

In FIG. 17, an example of setting the end point of the current restriction section 80 according to the relationship between the number of the lithium-ion batteries 41 and β. The BMU 50 may set the starting point of the current restriction section 80 by the same method as the setting method described in FIG. 17. That is, in the cases in which a plurality of lithium-ion batteries 41 are included, the setting unit 53 may set the starting point and the end point of the current restriction section 80 based on the voltage change rates of one or more of the plurality of lithium-ion batteries 41.

The method for setting the starting point and the end point of the current restriction section 80 may be expressed as follows. (a) The setting unit 53 sets the starting point and the end point of the current restriction section 80 based on the voltage change rates of one or more but less than half of the lithium-ion batteries 41. (b) The setting unit 53 sets the starting point and the end point of the current restriction section 80 based on the voltage change rates of half or more of the lithium-ion batteries 41. When the charge is performed a plurality of times in a predetermined period, the frequency of executing the setting of (a) is, with respect to the number of times of charge, higher than the frequency of executing the setting of (b). (a) corresponds to the case 2, and (b) corresponds to the case 3. The frequency of executing the setting of (a) is three of ten times, and the frequency of executing the setting of (b) is two of ten times. That is, the frequency of the settings is frequency of (a)>frequency of (b).

(c) The setting unit 53 sets the starting point and the end point of the current restriction section 80 based on the voltage change rate of one lithium-ion battery 41. (d) The setting unit 53 sets the starting point and the end point of the current restriction section 80 based on the voltage change rates of all the lithium-ion batteries 41. When the charge is performed a plurality of times in a predetermined period, the frequency of executing the setting of (c) is, with respect to the number of times of charge, higher than the frequency of executing the setting of (d). (c) corresponds to the case 1, and (d) corresponds to the case 4. The frequency of executing the setting of (c) is four of ten times, and the frequency of executing the setting of (d) is one of ten times. That is, the frequency of the settings is frequency of (c)>frequency of (d).

The control unit and the method thereof described in the present disclosure may be achieved by a dedicated computer provided so as to include a processor, which is programmed to perform one or a plurality of functions embodied by a computer program, and a memory. Alternatively, the control unit and the method thereof described in the present disclosure may be achieved by a dedicated computer provided so as to include a processor formed of one or more dedicated hardware logic circuits. Alternatively, the control unit and the method thereof described in the present disclosure may be achieved by one or more dedicated computers configured to include a combination of a processor, which is programmed to perform one or a plurality of functions, and a memory, with a processor formed of one or more hardware logic circuits. The computer program may be, as instructions to be performed by a computer, stored in a computer-readable non-transitory tangible storage medium.

Hereinafter, characteristic configurations extracted from the embodiments are described.

### [Configuration 1]

A capacity estimation device that estimates a capacity of a power storage unit (41) at a time of charging the power storage unit,

the capacity estimation device including:

a control unit (54) configured to reduce an average current in a predetermined current restriction section after a start of charging the power storage unit, the average current indicating an average value per unit time of a charging current flowing in the power storage unit; and

an estimation unit (55) configured to estimate the capacity based on a voltage change rate of the power storage unit after or within the current restriction section.

### [Configuration 2]

The capacity estimation device according to configuration 1, including a setting unit configured to set the current restriction section based on a parameter that changes by charging the power storage unit.

### [Configuration 3]

The capacity estimation device according to configuration 1 or 2, wherein

the parameter is the voltage change rate of the power storage unit, and

the setting unit is configured to set, as a starting point of the current restriction section, a point at which the voltage change rate is a first predetermined value or lower.

### [Configuration 4]

The capacity estimation device according to any one of configurations 1 to 3, wherein

the setting unit is configured to set, as an end point of the current restriction section, a point at which the voltage change rate is higher than the first predetermined value, and

the control unit is configured to increase the average current after the current restriction section.

### [Configuration 5]

The capacity estimation device according to any one of configurations 1 to 4, wherein

the setting unit is configured to set, as the end point of the current restriction section, a point at which the voltage change rate is higher than the first predetermined value and which is before the voltage change rate has a local maximum, and

the control unit is configured to increase the average current after the current restriction section.

### [Configuration 6]

The capacity estimation device according to any one of configurations 1 to 5, wherein the estimation unit is configured to estimate, as the capacity of the power storage unit, a capacity corresponding to between two local minimums that the voltage change rate has after or within the current restriction section.

### [Configuration 7]

The capacity estimation device according to any one of configurations 1 to 6, wherein

within the current restriction section,

the lower a temperature related to the power storage unit, the more the control unit reduces the average current, or

the longer a lapse of time from production of the power storage unit, the more the control unit reduces the average current.

### [Configuration 8]

The capacity estimation device according to any one of configurations 1 to 7, wherein

within the current restriction section,

the higher a temperature related to the power storage unit, the more the control unit increases the average current, or

the shorter a lapse of time from production of the power storage unit, the more the control unit reduces the average current.

### [Configuration 9]

The capacity estimation device according to any one of configurations 1 to 8, wherein when a plurality of the power storage units are included, the setting unit is configured to set the starting point and the end point of the current restriction section based on the voltage change rates of one or more of the plurality of the power storage units.

### [Configuration 10]

The capacity estimation device according to any one of configurations 1 to 9, wherein when a plurality of the power storage units are included,

(a) the setting unit is configured to set the starting point and the end point of the current restriction section based on the voltage change rates of one or more but less than half of the power storage units, or

(b) the setting unit is configured to set the starting point and the end point of the current restriction section based on the voltage change rates of half or more of the power storage units, and

when charge is performed a plurality of times in a predetermined period, a frequency of executing a setting of (a) is, with respect to the number of times of charge, higher than a frequency of executing a setting of (b).

### [Configuration 11]

The capacity estimation device according to any one of configurations 1 to 10, wherein when a plurality of the power storage units are included,

(c) the setting unit is configured to set the starting point and the end point of the current restriction section based on the voltage change rate of one of the power storage units, or

(d) the setting unit is configured to set the starting point and the end point of the current restriction section based on the voltage change rates of all the power storage units, and

when charge is performed a plurality of times in a predetermined period, a frequency of executing a setting of (c) is, with respect to the number of times of charge, higher than a frequency of executing a setting of (d).

### [Configuration 12]

The capacity estimation device according to any one of configurations 1 to 11, wherein the estimation unit is configured to estimate that the voltage change rate has a local maximum, when the voltage change rate goes from less than a second predetermined value (K), beyond a third predetermined value (B) higher than the second predetermined value, and then to less than a fourth predetermined value (C) lower than the third predetermined value.

### [Configuration 13]

The capacity estimation device according to any one of configurations 1 to 12, wherein the estimation unit is configured to estimate that the voltage change rate has a local maximum, when a change rate of a temperature related to the power storage unit or a voltage change rate of impedance in the power storage unit changes beyond a fifth predetermined value.

### [Configuration 14]

The capacity estimation device according to any one of configurations 1 to 13, further including a calculation unit configured to calculate a degradation state of the power storage unit based on the capacity estimated by the estimation unit, a current integrated value obtained by integrating the charging current applied and the time taken from the estimation of the capacity until the power storage unit satisfies a full-charge condition, and a full capacity when the power storage unit is new.

### [Configuration 15]

A capacity estimation method that estimates a capacity of a power storage unit (41) at a time of charging the power storage unit,

the capacity estimation method including:

reducing an average current in a predetermined current restriction section after a start of charging the power storage unit, the average current indicating an average value per unit time of a charging current flowing in the power storage unit; and

estimating the capacity based on a voltage change rate of the power storage unit after or within the current restriction section.

The present disclosure has been described in accordance with the examples, but is to be understood not to be limited to the examples and the structures thereof. The present disclosure embraces various modified examples and modifications within the range of equivalency. In addition, various combinations and forms, and other combinations and forms including more, less, or only a single element are also within the spirit and scope of the present disclosure.

What is claimed is:

1. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit;
an estimation unit configured to estimate the capacity based on a voltage change rate of the power storage unit after or within the current restriction section; and
a setting unit configured to set the current restriction section based on a parameter that changes by charging the power storage unit,
wherein
the parameter is the voltage change rate of the power storage unit,
the setting unit is configured to:
set, as a starting point of the current restriction section, a point at which the voltage change rate is a first predetermined value or lower, and
set, as an end point of the current restriction section, a point at which the voltage change rate is higher than the first predetermined value, and
the control unit is configured to increase the average current after the current restriction section.

2. The capacity estimation device according to claim 1, wherein
the setting unit is configured to set, as the end point of the current restriction section, a point at which the voltage change rate is higher than the first predetermined value and which is before the voltage change rate has a local maximum, and
the control unit is configured to increase the average current after the current restriction section.

3. The capacity estimation device according to claim 1, wherein when a plurality of the power storage units are included, the setting unit is configured to set the starting point and the end point of the current restriction section based on the voltage change rates of one or more of the plurality of the power storage units.

4. The capacity estimation device according to claim 3, wherein when a plurality of the power storage units are included,
(a) the setting unit is configured to set the starting point and the end point of the current restriction section based on the voltage change rates of one or more but less than half of the power storage units, or
(b) the setting unit is configured to set the starting point and the end point of the current restriction section based on the voltage change rates of half or more of the power storage units, and
when charge is performed a plurality of times in a predetermined period, a frequency of executing a setting of (a) is, with respect to the number of times of charge, higher than a frequency of executing a setting of (b).

5. The capacity estimation device according to claim 4, wherein when a plurality of the power storage units are included,
(c) the setting unit is configured to set the starting point and the end point of the current restriction section based on the voltage change rate of one of the power storage units, or
(d) the setting unit is configured to set the starting point and the end point of the current restriction section based on the voltage change rates of all the power storage units, and
when charge is performed a plurality of times in a predetermined period, a frequency of executing a setting of (c) is, with respect to the number of times of charge, higher than a frequency of executing a setting of (d).

6. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit; and
an estimation unit configured to estimate the capacity based on a voltage change rate of the power storage unit after or within the current restriction section,
wherein the estimation unit is configured to estimate, as the capacity of the power storage unit, a capacity corresponding to between two local minimums that the voltage change rate has after or within the current restriction section.

7. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit; and
an estimation unit configured to estimate the capacity based on a voltage change rate of the power storage unit after or within the current restriction section,
wherein
within the current restriction section,
the lower a temperature related to the power storage unit, the more the control unit reduces the average current, or
the longer a lapse of time from production of the power storage unit, the more the control unit reduces the average current.

8. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit; and
an estimation unit configured to estimate the capacity based on a voltage change rate of the power storage unit after or within the current restriction section,
wherein
after the current restriction section,
the higher a temperature related to the power storage unit, the more the control unit increases the average current, or
the shorter a lapse of time from production of the power storage unit, the more the control unit increases the average current.

9. The capacity estimation device according to claim 1, further comprising a calculation unit configured to calculate a degradation state of the power storage unit based on the capacity estimated by the estimation unit, a current integrated value obtained by integrating the charging current applied and the time taken from the estimation of the capacity until the power storage unit satisfies a full-charge condition, and a full capacity when the power storage unit is new.

10. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit; and
an estimation unit configured to estimate the capacity based on a voltage change rate of the power storage unit after or within the current restriction section,
wherein the estimation unit is configured to estimate that the voltage change rate has a local maximum, when the voltage change rate goes from less than a second predetermined value, beyond a third predetermined value higher than the second predetermined value, and then to less than a fourth predetermined value lower than the third predetermined value.

11. A capacity estimation device that estimates a capacity of a power storage unit at a time of charging the power storage unit,
the capacity estimation device comprising:
a control unit configured to reduce an average current in a predetermined current restriction section after a start of charging the power storage unit, the average current indicating an average value per unit time of a charging current flowing in the power storage unit; and
an estimation unit configured to estimate the capacity based on a voltage change rate of the power storage unit after or within the current restriction section,
wherein the estimation unit is configured to estimate that the voltage change rate has a local maximum, when a change rate of a temperature related to the power storage unit or a voltage change rate of impedance in the power storage unit changes beyond a fifth predetermined value.

12. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit;
an estimation step for estimating the capacity based on a voltage change rate of the power storage unit after or within the current restriction section; and
a setting step for setting the current restriction section based on a parameter that changes by charging the power storage unit,
wherein
the parameter is the voltage change rate of the power storage unit,
in the setting step:
a point at which the voltage change rate is a first predetermined value or lower is set as a starting point of the current restriction section, and
a point at which the voltage change rate is higher than the first predetermined value is set as an end point of the current restriction section, and
in the control step, the average current is increased after the current restriction section.

13. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit; and
an estimation step for estimating the capacity based on a voltage change rate of the power storage unit after or within the current restriction section,
wherein in the estimation step, a capacity corresponding to between two local minimums that the voltage change rate has after or within the current restriction section is estimated as the capacity of the power storage unit.

14. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit; and
an estimation step for estimating the capacity based on a voltage change rate of the power storage unit after or within the current restriction section,
wherein in the control step, within the current restriction section,
the lower a temperature related to the power storage unit, the more the average current is reduced, or
the longer a lapse of time from production of the power storage unit, the more the average current is reduced.

15. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit; and
an estimation step for estimating the capacity based on a voltage change rate of the power storage unit after or within the current restriction section,
wherein in the control step, after the current restriction section,
the higher a temperature related to the power storage unit, the more the average current is increased, or
the shorter a lapse of time from production of the power storage unit, the more the average current is increased.

16. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit; and
an estimation step for estimating the capacity based on a voltage change rate of the power storage unit after or within the current restriction section,
wherein in the estimation step, it is estimated that the voltage change rate has a local maximum, when the voltage change rate goes from less than a second predetermined value, beyond a third predetermined value higher than the second predetermined value, and then to less than a fourth predetermined value lower than the third predetermined value.

17. A capacity estimation method that estimates a capacity of a power storage unit at a time of charging the power storage unit,
the capacity estimation method comprising:
a control step for reducing an average current in a predetermined current restriction section after a start of charging the power storage unit, the average current indicating an average value per unit time of a charging current flowing in the power storage unit; and
an estimation step for estimating the capacity based on a voltage change rate of the power storage unit after or within the current restriction section,
wherein in the estimation step. it is estimated that the voltage change rate has a local maximum. when a change rate of a temperature related to the power storage unit or a voltage change rate of impedance in the power storage unit changes beyond a fifth predetermined value.
